(19) United States
(12) Patent Application Publication
(10) Pub. No.: US 2005/0008055 A1
(43) Pub. Date: Jan. 13, 2005

(54) Facet passivation for edge emitting semiconductor lasers

(75) Inventor: Chen Tirong, Azusa, CA (US)

Correspondence Address: FULBRIGHT AND JAWORSKI L L P;PATENT DOCKETING 29TH FLOOR, 865 SOUTH FIGUEROA STREET, LOS ANGELES, CA, 900172576, US

(73) Assignee: ARCHCOM TECHNOLOGY, INC., Azusa, CA (US)

(21) Appl. No.: 10/857,060

(22) Filed: May 28, 2004

Related U.S. Application Data
(60) Provisional application No. 60/474,715, filed on May 30, 2003.

(51) Int. Cl. H01L 21/00; H01S 5/00

(52) U.S. Cl. 372/43; 438/22

(57) ABSTRACT

A continuous monolithic QW layer of an edge-emitting semiconductor laser includes a passivated window section adjacent each facet and an active section between the two window sections. The thickness of each QW layer in the window section is sufficiently less than the corresponding thickness in the active section to cause the window section to be non-absorptive to any laser emissions in the vicinity of the facet mirror. The QWs in both the window section and the active section are preferably formed in a single metal organic chemical vapor deposition (MOCVD) growth step without any disturbance in the layer continuity.

### CROSS-REFERENCE TO RELATED APPLICATION

This application is based on U.S. Provisional Patent Application Ser. No. 60/474,715, filed May 30, 2003.

### FIELD OF THE INVENTION

The present invention is generally related to edge emitting semiconductor lasers and more specifically related to improved techniques for facet passivation that will reduce failures at higher power levels.

### BACKGROUND

AlGaAs/InGaAs/GaAs material system is widely used in current 980 nm pump lasers. A critical issue related to 980 nm pump laser's application is reliability at high optical power level.

A phenomenon called COD (Catastrophic Optical Damage) of the laser facet mirror is a major cause of failure for high power semiconductor lasers. COD is exacerbated by concentrations of laser energy at defects or discontinuities in the active region adjacent the facet surface in the active region adjacent the fact surface, which causes the accelerated optical power absorption, and thus, thermal runaway in the facet mirror region. Therefore, the semiconductor material in the vicinity of the facet surfaces of such lasers is preferably processed in such a way as to reduce COD in what may be generically termed “facet passivation”.

Among the facet passivation approaches that have been proposed for 980 nm pump lasers may be included the following:
Forming the facet surface by cleaving in a vacuum, which results in fewer COD causing defects, but requires relatively complex and expensive equipment.
Forming a barrier region in a window section of the QW (Quantum Well) structure between the active region and the facet, which reduces concentrations of laser energy adjacent the facet surface but adds additional process steps and could potentially create other failure inducing defects in the active region.
Depositing a different material with a wider band-gap (compared to that of the active layer material) to thereby form a separate non-absorptive window region for the facet, which also involves additional processing and which could also result in other incidental defects.

Patterned substrate selective-area epitaxial growth technology is a powerful growth tool for lateral band-gap engineering of semiconductor lasers.

### SUMMARY

In one embodiment of the present invention, a continuous monolithic QW layer of an edge-emitting semiconductor laser includes a passivated window section adjacent each facet and an active section between the two window sections. The thickness of each QW layer in the window section is sufficiently less than the corresponding thickness in the active section to cause the window section to be non-absorptive to any laser emissions in the vicinity of the facet mirror. The QWs in both the window section and the active section are preferably formed in a single metal organic chemical vapor deposition (MOCVD) growth step without any disturbance in the layer continuity. Since both the window section and the active section are thus formed in the same growth step using the same mask, defects that might happen in other passivation technologies, such as the regrowth of a separate window section or a subsequent ion implantation to isolate the window section from the active section, are thereby avoided. Although particularly suitable for use in a 980 mn pump laser, the disclosed passivation technology can be applied to any laser for which a non-absorption facet mirror is needed, and can also be used in a monolithic integration configuration, such as a laser and a non-absorption waveguide, a laser and an external modulator (with properly applied voltage), or a laser and a detector.

### DRAWINGS

FIG. 1 is a plan diagram of a patterned substrate for selective area growth.

FIG. 2 comprising FIGS. 2a through 2c shows alternative embodiments of the patterned substrate of FIG. 1.

FIG. 3 shows a simplified version of the mask of FIG. 2a, replicated in adjacent cells on a substrate.

FIG. 4 is an isometric oblique view of an exemplary RW 980 nm pump laser.

FIG. 5 is a schematic cross section of the layered structure for the exemplary 980 nm pump laser of FIG. 4.

FIG. 6 is a band gap energy diagram of layered structure of FIG. 5 in the active region of FIG. 4.

FIG. 7 is a band gap energy diagram of the layered structure of FIG. 5 in the window region of FIG. 4.

### DESCRIPTION OF A PREFERRED EMBODIMENT

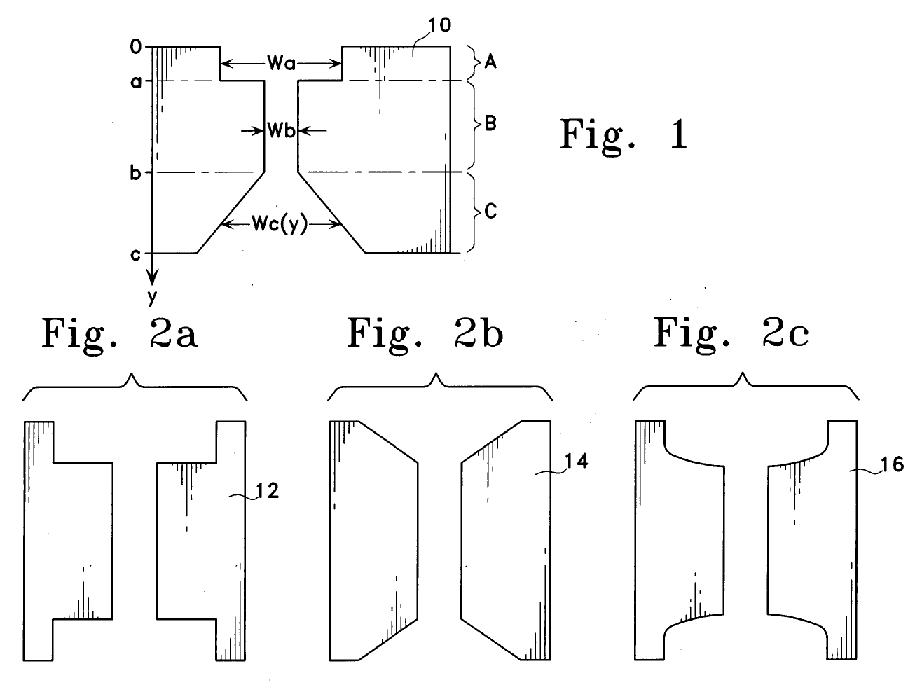

The growth dynamics of a typical patterned substrate selective-area epitaxial growth technology, will now be described with reference to FIG. 1. Suppose the substrate on which epitaxial layers are intended to be grown is masked with thin film such as SiO₂, Si₃N₄. Openings in sections A, B, C of mask 10 are made on the substrate with respective widths Wa, Wb and Wc(y). When a metal organic chemical vapor deposition (MOCVD) reactor is used for epi-layer growth, the epi-layers will only grow in the opening area, not in the area masked by SiO₂ or Si₃N₄. Furthermore, the growth rate and thus the grown epi-layer thickness depend on the dimension of opening, the wider the opening is, the slower the growth rate will be. Therefore, in the example shown in FIG. 1, the growth rate Ra and layer thickness Da in section A is smaller than the corresponding rate Rb and resultant thickness Db in section B. In section C, the growth rate Rc(y) and layer thickness Dc(y) vary along the y direction due to the width (Wc) variation.

Now assume that this same mask is used to grow Quantum Wells (QWs). In that case, the QW thickness in section A will be smaller than that in section B. The QW thickness in section C will gradually decrease from y=b to y=c. Since the thinner QW will support a correspondingly shorter emission wavelength, the characteristic (ground state transition) wavelength λ of sections A, B and C will be different, λₐ<λ_{b}, λ_{c}=λ_{c}(y)<λ_{b}. Note that λ_{c} decreases from y=b to y=c.

Now imagine that section B is the desired active region of a QW 980 nm pump laser, then section A and C will be ideal non-absorption regions and will provide facet passivation when the laser facets are formed in section A and C.

Exemplary alternative non-absorptive laser window configurations are illustrated in FIG. 2a through FIG. 2c. The step flare mask 12 of FIG. 2a has performance characteristic similar to the A and B portions of the FIG. 1 mask 10, while the linear mask 14 of FIG. 2b has performance characteristic similar to the C and B portions of the FIG. 1 mask 10. The curved flare mask 16 of FIG. 2c is similar to the linear flare mask 14 of FIG. 2b, but Rc(y) and Dc(y) will have non-linear performance characteristics.

Windows can be designed with different topologies. In all cases, the effective width of the mask opening in the window area in the vicinity of the facet is larger than that in the active area.

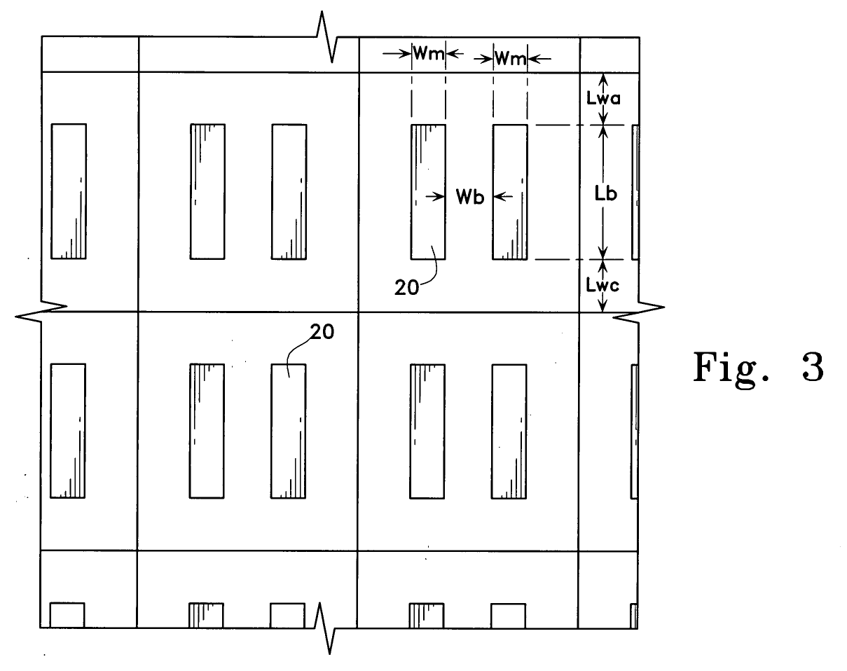

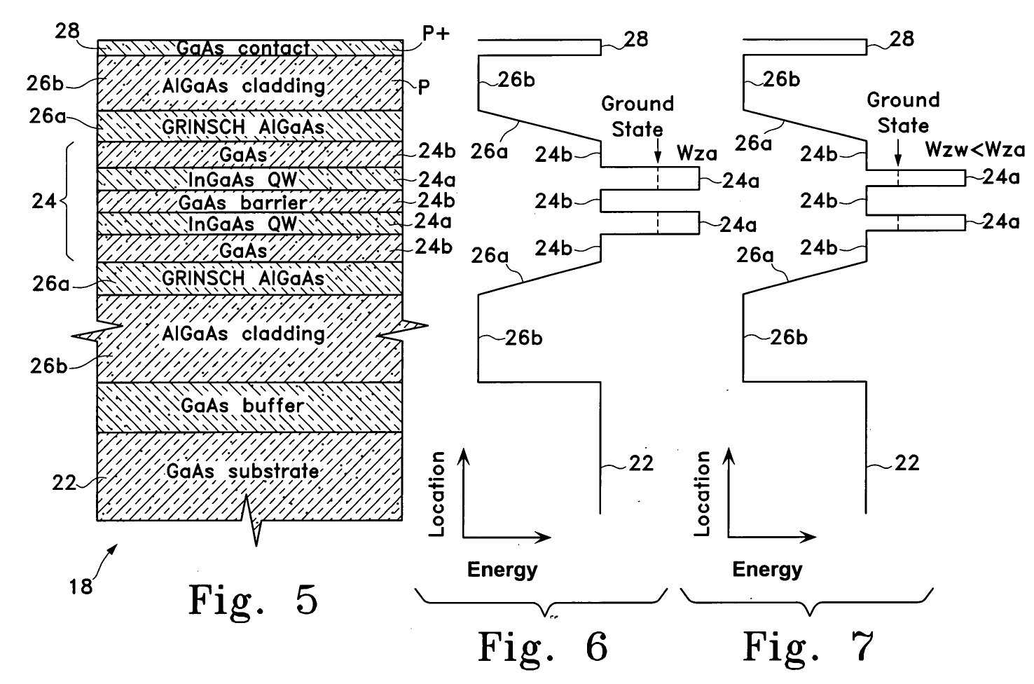

FIG. 5 depicts a schematic structure for an exemplary 980 nm pump laser 18 incorporating one embodiment of the improved passivation technology of the present invention. This particular example is based on a III-V compound semiconductor material system (AlGaAs/InGaAs/GaAs) which has been widely used for 980 nm pump lasers, and uses a simplified variant 20 of the step flare mask 12 of FIG. 2a, as shown in FIG. 3

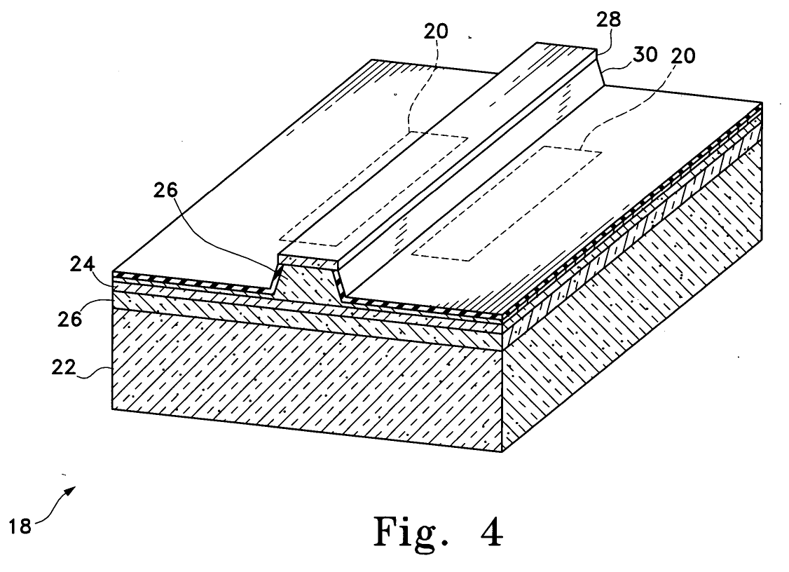

High quality single crystal GaAs wafer is used as an n type substrate 22. Active layer 24 includes one or more QW layers 24a of strained InGaAs QWs to emit at 980 nm wavelength, each sandwiched (as shown in more detail in FIG. 5) between Quantum Barrier (QB) and confinement layers 24b made of GaAs material. AlGaAs with varying Al composition is used as GRINSCH (Graded Index Separate Confinement Heterostructure) layers 26a to provide optical and electrical confinement in transverse direction. Upper cladding layer 26b forms a ridge-waveguide (RW) structure (see FIG. 4) which provides optical and electrical confinement in the lateral direction over the active region Wb (see FIG. 3), to ensure low threshold and single lateral mode operation. An electrical contact 28 may be formed of p+ type GsAs.

A conventional insulator may be provided over the exposed upper surface of cladding layer 26b, and conventional dielectric coatings are provided at the cleaved facets at either end of the RW structure to provide the desired reflectivity at either end of the laser cavity, preferably optimized to improve forward power and/or to facilitate wavelength locking by fiber Bragg grating (FBG).

The following is a brief description of the main process steps used in the manufacture of an exemplary 980 nm pump laser such as that depicted in FIG. 4:
Pattern formation on a GaAs substrate wafer to define active and window portions in each of a plurality of adjacent devices, with the width of the active portions being substantially less than a corresponding dimension of the window portions.
Selective area epitaxial growth on the patterned GaAs substrate to form one or more layers of a continuous QW/QB structure having active and window portions of different thickness.
Depositions of other required structures over the QW/QB structure.
Cleaving the wafer into individual devices.
Application of dielectric coatings to front and rear facets of each device.

To best protect the reflective laser facets from COD, the difference in QW width (thickness of the individual QW layers) in the window area and active area should be large enough to eliminate residual absorption in the window region while still being optimized for laser emissions in the active region. This can be obtained by sizing the respective openings in the corresponding sections in accordance with the known growth characteristics of the MOCVD process to produce the required layer thickness in each region. In particular, for the simple mask 20, the width Wb and length Lb are first determined in accordance with the desired dimensions of the active portion for a particular desired thickness Db, and then width dimension Wm and length dimensions Lwa, Lwc of the window section can be determined to provide a sufficiently different thickness range Da,Dc in the adjacent window region 30 surrounding masks 20 and active region Wb.

Reference should also be made to the energy level diagrams of FIG. 6 (corresponding to the active portion of the FIG. 4 device) and of FIG. 7 (corresponding to the window portion of that same device). In particular, note that the QW layer thickness (Wzw) in the window section is smaller than the corresponding QW layer thickness (Wza) in the active section, and that the ground state energy level which defines the associated wavelength is higher for the active portion.

Since the QW thickness in the window section is always smaller than that in the active section, it is thus non-absorptive in the vicinity of the facet mirror. Moreover, since the QWs in the window and active section are formed in a single MOCVD growth step, there is no disturbance in the layer continuity, thus avoiding the introduction of any defects that might happen in other technologies, such as the regrowth of a window section or ion implantation.

The process sequence may be varied from that described, and may include other layers and other structures. In particular, the patterning may be formed earlier or later, as long as it is in place when the active layer quantum well/quantum barrier is selectively grown. Moreover, those skilled in the art will recognize that otherwise conventional performance enhancement strategies may also be utilized, including the design optimization of the active QW structure for high power, single mode operation and desired spectral profile, and the coating optimization for high forward output power and wavelength locking stability.

Those skilled in the art will also recognize that the inventive concepts underlying the disclosed embodiments can also applied to other laser devices in which a non-absorption facet mirror is desirable, as well as to lasers monolithically integrated with other semiconductor devices in which an absorptive component is interfaced with a non absorptive component, such as a laser and a non-absorption waveguide, a laser and an external modulator, or a laser and detector.

1. In a process for fabricating an edge-emitting semiconductor laser including the epitaxial growth of a continuous quantum well layer extending into separated window portions of the laser, and the subsequent formation of a respective facet window in each of said window portions
ensuring that the thickness of said quantum well layer in the vicinity of each facet is smaller than the thickness of said layer within an active section between said window portions.

2. The process of claim 1 wherein the continuous quantum well layer is absorptive in said active section for a predetermined laser emission wavelength and is non-absorptive in the vicinity of said facets.

3. The process of claim 1 wherein both the active section of the continuous quantum well layer and the window portions of said layer are formed at the same time using the same opening of a common mask.

4. The process of claim 3 wherein the common mask defines an elongated active area having a first width, said elongated area being terminated at each end with a respective window area having a respective width greater than said first width.

5. The process of claim 4 wherein each said facet is formed at a location in a respective window area in which said respective width is substantially greater than said first width.

6. The process of claim 1 wherein the continuous quantum well layer is grown by means of a patterned substrate selective-area epitaxial growth technology.

7. The process of claim 6 wherein the patterned substrate selective-area epitaxial growth technology is metal-organic chemical vapor deposition.

8. The process of claim 1 wherein the continuous quantum well layer is grown by means of molecular beam epitaxy.

9. Process for forming an edge-emitting semiconductor laser, comprising:
forming a pattern on a substrate defining an opening including an elongated active area leading at each end into a respective window area, each window area having a width in a lateral dimension greater than the corresponding width of the active area; and
using said pattern opening to grow a corresponding epitaxial quantum well layer, such that the thickness of the quantum well layer is greater in the active area than in the window areas.

10. An edge-emitting semiconductor laser device, comprising:
a substrate;
a first cladding layer formed on the substrate;
a second cladding layer formed above the first cladding layer;
a first facet mirror defined on a first edge of the laser device;
a second facet mirror defined on a second edge of the laser device; and
a continuous quantum well/quantum barrier structure sandwiched between the first and second cladding layers and extending between the first and second facet mirrors, said quantum well/quantum barrier structure including at least one quantum well layer,
wherein the thickness of each said quantum well layer in the vicinity of each facet is smaller than the thickness of said layer within an active section between said facets such that, for a predetermined laser emission wavelength, the continuous quantum well layer is absorptive in said active section and is non-absorptive in the vicinity of said facets.

11. A method for manufacturing an integrated optical device comprising:
growing a continuous quantum well layer extending into separated active and passive portions of the integrated device; and
ensuring that the thickness of said quantum well layer in the vicinity of an active portion of said device is greater than the thickness of said layer within a passive portion of said device such that, for a predetermined laser emission wavelength, the continuous quantum well layer is absorptive in said active portion and is non-absorptive in said passive portion

12. The method of 11 wherein both the absorptive portion of the continuous quantum well layer and said non-absorptive portion of said layer are deposited onto a patterned substrate formed at the same time though a single opening.

13. The method of 12 wherein said single opening defines a narrow area over said active portion and a wider area over said passive portion width.
